(19) United States
(12) Patent Application Publication
(10) Pub. No.: US 2022/0081757 A1
(43) Pub. Date: Mar. 17, 2022

(54) FILM FORMING APPARATUS, FILM FORMING SYSTEM, AND FILM FORMING METHOD

(71) Applicant: TOKYO ELECTRON LIMITED, Tokyo (JP)

(72) Inventors: Masato Shinada, Tokyo (JP); Naoki Watanabe, Yamanashi (JP); Tetsuya Miyashita, Yamanashi (JP); Hiroyuki Toshima, Yamanashi (JP); Einstein Noel Abarra, Tokyo (JP); Shota Ishibashi, Yamanashi (JP)

(21) Appl. No.: 17/469,250

(22) Filed: Sep. 8, 2021

(30) Foreign Application Priority Data
Sep. 11, 2020 (JP) 2020-152522
Jan. 19, 2021 (JP) 2021-006406

(51) Int. Cl. C23C 14/34; C23C 14/54

(52) U.S. Cl. CPC C23C 14/34; C23C 14/54

(57) ABSTRACT

A film forming apparatus is provided. The apparatus comprises a processing chamber accommodating a plurality of substrates; a plurality of substrate supporting units disposed in the processing chamber and configured to place the substrates thereon; a substrate moving mechanism configured to linearly move the substrate supporting units in a first direction; sputter particle emitting units, each having a target for emitting sputter particles into the processing chamber; and a controller configured to control the sputter particle emitting units and the substrate moving mechanism. The controller controls the substrate moving mechanism to linearly move the substrate supporting units on which the substrates are placed in the first direction and controls the sputter particle emitting units to emit sputter particles to be deposited on the substrates.

### CROSS-REFERENCE TO RELATED APPLICATIONS

This application claims priority to and the benefit of Japanese Patent Application Nos. 2020-152522 and 2021-006406 filed on Sep. 11, 2020 and Jan. 19, 2021, respectively, which are incorporated herein by reference in their entirety.

### TECHNICAL FIELD

The present disclosure relates to a film forming apparatus, a film forming system, and a film forming method.

### BACKGROUND

In manufacturing electronic devices such as semiconductor devices, a film forming process for forming a film on a substrate is performed. As a film forming apparatus used for the film forming process, a sputter film forming apparatus for emitting sputter particles from a target and depositing the sputter particles on a substrate is known.

As a technique for performing sputter film formation, Japanese Patent Application Publication 2020-26575 discloses a single-wafer film forming apparatus for performing oblique film formation by depositing sputter particles emitted from two targets on a substrate that is linearly moved in a processing space in a chamber.

### SUMMARY

The present disclosure provides a film forming apparatus, a film forming system, and a film forming method capable of saving a space by performing film formation with a high throughput.

A film forming apparatus comprising a processing chamber accommodating a plurality of substrates; a plurality of substrate supporting units disposed in the processing chamber and configured to place the substrates thereon; a substrate moving mechanism configured to linearly move the substrate supporting units in a first direction; sputter particle emitting units, each having a target for emitting sputter particles into the processing chamber; and a controller configured to control the sputter particle emitting units and the substrate moving mechanism is provided, wherein the controller controls the substrate moving mechanism to linearly move the substrate supporting units on which the substrates are placed in the first direction and controls the sputter particle emitting units to emit sputter particles to be deposited on the substrates.

### BRIEF DESCRIPTION OF THE DRAWINGS

The objects and features of the present disclosure will become apparent from the following description of embodiments, given in conjunction with the accompanying drawings, in which:

FIG. 1 is a schematic plan view showing a film forming system including a film forming apparatus;

FIG. 2 is a vertical cross-sectional view showing an example of the film forming apparatus;

FIG. 3 is a horizontal cross-sectional view taken along a line of FIG. 2;

FIG. 4 is a cross-sectional view showing a preliminary chamber having a function of rotating a substrate;

FIGS. 5A to 5F explain an outline of movement of substrates in an example of a film forming method;

FIGS. 6A to 6J are plan views for explaining a transfer state of the substrates in the case of implementing an example of the film forming method;

FIGS. 7A and 7B are cross-sectional views for explaining a state in which the substrate is transferred from a vacuum transfer device in a vacuum transfer chamber to a substrate supporting unit of the film forming apparatus in the case of performing an example of the film forming method;

FIGS. 8A and 8B are cross-sectional views for explaining a state in which the substrate is transferred from the substrate supporting unit of the film forming apparatus to the vacuum transfer device in the vacuum transfer chamber in the case of performing an example of the film forming method;

FIG. 9 is a cross-sectional view showing an example in which film formation is performed by emitting sputter particles from one target while moving a substrate;

FIG. 10 is a cross-sectional view showing a state in which sputter film formation is performed on a substrate having a trench pattern in the example of FIG. 9;

FIG. 11 is a cross-sectional view showing an example in which film formation is performed by emitting sputter particles from the other target while moving a substrate;

FIG. 12 is a cross-sectional view showing a state in which sputter film formation is performed on a substrate having a trench pattern in the example of FIG. 11;

FIG. 13 is a cross-sectional view showing an example in which film formation is performed by emitting sputter particles from both targets while moving a substrate;

FIG. 14 is a cross-sectional view showing a state in which sputter film formation is performed on a substrate having a trench pattern in the example of FIG. 13;

FIG. 15 is a cross-sectional view showing an example of improving directivity by changing a position of a hole through which sputter particles pass in the case of performing film formation by emitting the sputter particles from the target while moving the substrate;

FIG. 16 is a cross-sectional view showing a state in which sputter film formation is performed on a substrate having a trench pattern in the example of FIG. 15;

FIG. 17 is a cross-sectional view showing an example in which the preliminary chamber is used as a part of a processing chamber;

FIG. 18 is a schematic plan view showing a film forming system including the film forming apparatus disclosed in Japanese Patent Application Publication 2020-26575;

FIG. 19 is a side view showing another example of a substrate moving mechanism;

FIG. 20 is a plan view showing still another example of the substrate moving mechanism;

FIG. 21 is a side view showing further still another example of the substrate moving mechanism;

FIGS. 22A to 22J explain movement of substrates in the case of performing another example of the film forming method;

FIGS. 23A to 23F explain an outline of the movement of three substrates in the case of performing a film forming process on the three substrates;

FIGS. 24A to 24F explain an outline of movement of four substrates arranged in a 2×2 matrix shape in an X direction that is a movement direction of the substrates and a Y direction perpendicular to the X direction in the case of performing film formation on the substrates.

### DETAILED DESCRIPTION

Hereinafter, embodiments will be described in detail with reference to the accompanying drawings.

<Film Forming System>

First, a film forming system including a film forming apparatus will be described.

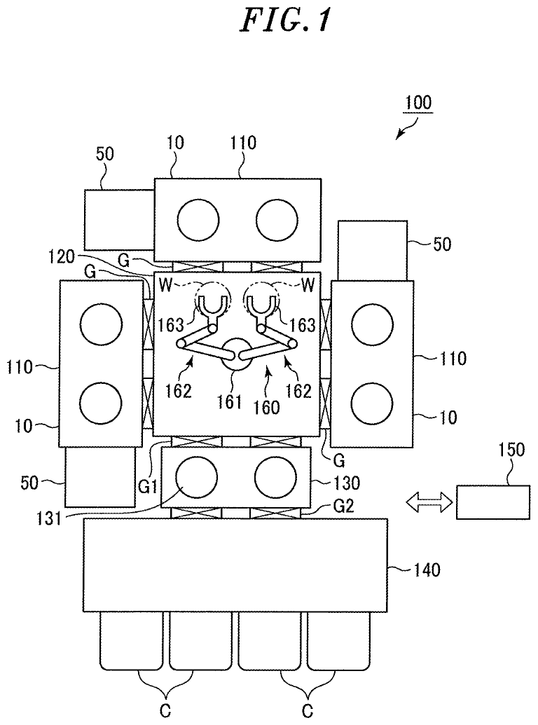

FIG. 1 is a schematic plane view showing a film forming system including a film forming apparatus.

A film forming system 100 of the present embodiment includes a plurality of dual-wafer film forming apparatuses for performing sputter film formation on two substrates W to consecutively perform film formation on the two substrates W. The substrate W is not particularly limited, and may be, e.g., a semiconductor wafer.

The film forming system 100, which is a multi-chamber type system, includes three film forming apparatuses 110, a vacuum transfer chamber 120, a load-lock chamber 130, an atmospheric transfer chamber 140, and an overall controller 150.

The vacuum transfer chamber 120 has a square planar shape, and a pressure therein is reduced to a vacuum atmosphere. The film forming apparatus 110 is connected to the three walls of the vacuum transfer chamber 120 (each of the three walls corresponding to the three sides of the square shape) through two gate valves G. Further, the load-lock chamber 130 is connected to a wall of the vacuum transfer chamber 120 (the wall corresponding to the one remaining side of the square shape) through two gate valves G1. A vacuum transfer device 160 is disposed in the vacuum transfer chamber 120.

The atmospheric transfer chamber 140 is connected to the side of the load-lock chamber 130 that is opposite to the side facing the vacuum transfer chamber 120 through two gate valves G2.

The vacuum transfer device 160 in the vacuum transfer chamber 120 loads/unloads the substrates W into/from the film forming apparatuses 110 and the-load lock chamber 130. The vacuum transfer device 160 has a base 161, two multi joint arms 162 attached to the base 161, and two substrate holders 163 respectively disposed at the tip ends of the two multi joint arms 162. The two substrate holders 163 are configured to transfer two substrate W simultaneously. In other words, the vacuum transfer device 160 is configured to simultaneously receive or deliver two substrates W with respect to the load-lock chamber 130 and the film forming apparatus 110.

The film forming apparatus 110 is configured to accommodate two substrates W and perform film formation thereon. The film forming apparatus 110 has a processing chamber 10 formed in a horizontally elongated rectangular planar shape and provided with loading/unloading ports corresponding to the two gate valves G. The two substrates W are loaded/unloaded through the two loading/unloading ports. Further, a preliminary chamber 50 is disposed adjacent to the processing chamber 10. The film forming apparatus 110 will be described in detail later.

The load-lock chamber 130 controls the pressure between the atmospheric pressure and a vacuum at the time of transferring the wafer W between the atmospheric transfer chamber 140 and the vacuum transfer chamber 120. Two substrate supports 131, each for placing thereon the substrate W, are disposed in the load-lock chamber 130, and two substrates W are accommodated simultaneously in the load-lock chamber 130.

A load port (not shown) is disposed on a wall of the atmospheric transfer chamber 140 that is opposite to the wall facing the load-lock chamber 130, and carriers C are connected to the load port. The carriers C may be, e.g., a front opening unified pod (FOUP) or the like. The pressure in the atmospheric transfer chamber 140 is set to the atmospheric atmosphere, and, for example, downflow of clean air is generated therein. An atmospheric transfer device (not shown) for transferring the substrate W is disposed in the atmospheric transfer chamber 140. The atmospheric transfer device transfers the substrate W between the carriers C and the load-lock chamber 130 in a state where the load-lock chamber 130 is in the atmospheric atmosphere with the gate valves G2 opened.

The overall controller 150 is a computer, and includes a main controller having a CPU, an input device, an output device, a display device, and a storage device (storage medium). The overall controller 150, which is a high-level controller for controlling operations of individual components of the film forming system 100, controls controllers of the film forming apparatuses 110 or individual controllers for individually controlling the transfer devices in the vacuum transfer device 160 and the atmospheric transfer chamber, and the gate valves G, G1 and G2. The main controller controls the individual components based on a processing recipe that is a control program stored in a storage medium (hard disk, optical disk, semiconductor memory, or the like) built in the storage device.

The film forming system 100 operates as follows based on the processing recipe of the overall controller 150.

First, two substrates W are taken out from the carrier C connected to the load port by the atmospheric transfer device (not shown) in the atmospheric transfer chamber 140. The two gate valves G2 are opened, and the two substrates W are loaded into the load-lock chamber 130 in the atmospheric atmosphere. Then, the gate valves G2 are closed, and the load-lock chamber 130 into which the two substrates W are loaded is set to a vacuum state corresponding to the state in the vacuum transfer chamber 120. Next, the two gate valves G1 are opened, and the two substrates W in the load-lock chamber 130 are taken out by the two substrate holders 163 of the vacuum transfer device 160. Then, the gate valves G1 are closed. Next, the two gate valves G corresponding to one of the film forming apparatuses 110 are opened, and the two substrates W are loaded into that film forming apparatus 110 by the two substrate holders 163 of the vacuum transfer device 160. Thereafter, the substrate holders 163 are retreated from the corresponding film forming apparatus 110, and the gate valves G are closed to perform film formation.

Upon completion of the film formation in the film forming apparatus 110, the corresponding gate valves G are opened, and the substrate holders 163 of the vacuum transfer apparatus 160 take out the two substrates W from the film forming apparatus 110. Then, the gate valves G are closed, and the gate valves G1 are opened to transfer the two substrates W held by the substrate holders 163 into the load-lock chamber 130. Next, the gate valves G1 are closed to set the load-lock chamber 130 into which the substrates W are loaded to the atmospheric atmosphere, and the gate valves G2 are opened. Thereafter, an atmospheric transfer device (not shown) takes out the two substrates W from the load-lock chamber 130 and stores the two substrates W in the carrier C of the load port.

The above-described processes are performed on the plurality of substrates W simultaneously, and the film formation is performed on all the wafers W in the carrier C.

<Example of Film Forming Apparatus>

Next, an example of the film forming apparatus 110 will be described.

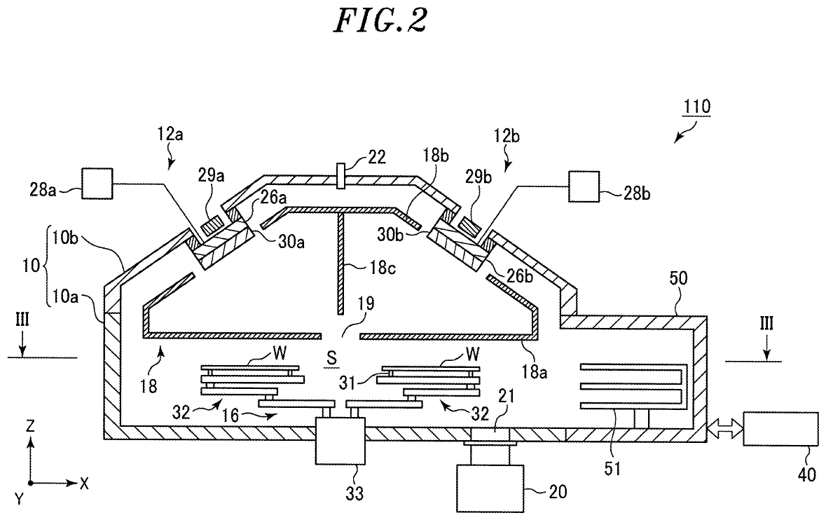

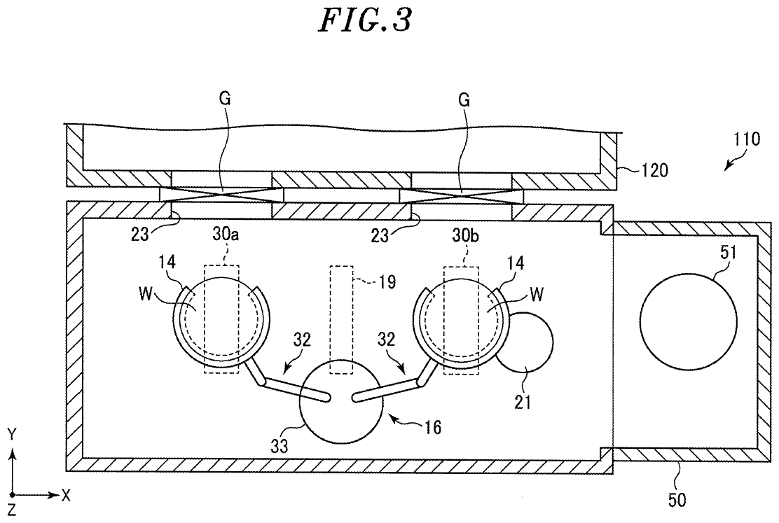

FIG. 2 is a vertical cross-sectional view showing an example of the film forming apparatus 110. FIG. 3 is a horizontal cross-sectional view taken along a line of FIG. 2.

The film forming apparatus 110 is a dual-wafer film forming apparatus for performing sputter film formation on two substrates W. The film forming apparatus 110 includes a processing chamber 10, first and second sputter particle emitting units 12a and 12b, two substrate supporting units 14, a substrate moving mechanism 16, a sputter particle shielding member 18, an exhaust device 20, and a controller 40. The film forming apparatus 110 further includes a preliminary chamber 50 adjacent to the chamber 10.

The processing chamber 10 has a chamber main body 10a having an upper opening and a lid 10b disposed to close the upper opening of the chamber main body 10a. The lid 10b has an inclined peripheral surface. The internal space of the processing chamber 10 serves as a processing space S in which film formation is performed.

As described above, the processing chamber 10 has a horizontally elongated rectangular shape. Two substrate loading/unloading ports 23 are disposed in parallel on one longitudinal side of the processing chamber 10, and the substrates W are loaded into and unloaded from the vacuum transfer chamber 120 through the substrate loading/unloading ports 23. The substrate loading/unloading ports 23 can be opened and closed by the gate valves G (see FIG. 3).

An exhaust port 21 is formed at a bottom portion of the processing chamber 10, and is connected to the exhaust device 20. The exhaust device 20 includes a pressure control valve and a vacuum pump, and is configured to vacuum-exhaust the processing space S to a predetermined vacuum level.

The preliminary chamber 50 is connected to the end portion of the processing chamber 10 in the X-direction (longitudinal direction) and communicates with the processing chamber 10. The preliminary chamber 50 is configured to perform multiple functions. In the example shown in FIGS. 2 and 3, the preliminary chamber 50 functions as a buffer unit for holding the substrates W when the substrates W cannot be unloaded in a timely manner during consecutive processing of the substrates W. In this example, a substrate support 51 having multiple stages in a height direction is disposed in the preliminary chamber 50. Alternatively, the substrate support 51 may have one stage.

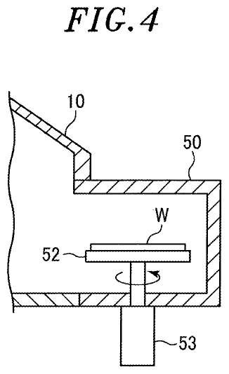

The preliminary chamber 50 may have a function of rotating the substrate W as well as the buffer function. Therefore, the preliminary chamber 50 includes a substrate support 52 on which the substrate W is placed and a rotation mechanism 53 for rotating the substrate support 52, as shown in FIG. 4. In addition, the preliminary chamber 50 may function as a part of the processing chamber 10 when sputter particles are incident on the substrate W at a low incident angle, as will be described later, in a state where the preliminary chamber 50 is empty.

A gas inlet port 22 for introducing a gas into the processing space S is inserted at the top of the processing chamber 10. A sputtering gas, e.g., an inert gas, is introduced into the processing space S from the gas inlet port 12.

The first sputter particle emitting unit 12a includes a target holder 26a, a target 30a held by the target holder 26a, a power supply 28a for applying a voltage to the target holder 26a, and a magnet 29a. The second sputter particle emitting unit 12b includes a target holder 26b, a target 30b held by the target holder 26b, a power supply 28b for applying a voltage to the target holder 26b, and a magnet 29b.

The target holders 26a and 26b are made of a conductive material and are attached to different positions on the inclined surface of the lid 10b of the processing chamber 10 via insulating members. In this example, the target holders 26a and 26b are disposed at positions opposite to each other. However, the present disclosure is not limited thereto, and the target holders 26a and 26b may be disposed at any other positions.

The targets 30a and 30b are made of a material containing a constituent element of a film to be formed, and may be made of a conductive material or a dielectric material. The targets 30a and 30b are held by the target holders 26a and 26b, respectively, and the length of the targets 30a and 30b in the Y direction is longer than a diameter of the substrate W.

The power supplies 28a and 28b are electrically connected to the target holders 26a and 26b, respectively. The power supplies 28a and 28b may be DC power supplies when the targets 30a and 30b are made of a conductive material, and may be radio frequency power supplies when the targets 30a and 30b are made of a dielectric material. When the power supplies 28a and 28b are the radio frequency power supplies, they are connected to the target holders 26a and 26b via matching units.

The magnets 29a and 29b are disposed on back surfaces of the target holders 26a and 26b, respectively. The magnets 29a and 29b apply leakage magnetic fields to the targets 30a and 30b, respectively, to perform magnetron sputtering. The magnets 29a and 29b are configured to move along the back surfaces of the target holders 26a and 26b, respectively, by a magnet driving unit (not shown).

By applying a voltage from the power supplies 28a and 28b to the targets 30a and 30b via the target holders 26a and 26b, respectively, the sputtering gas is dissociated around the targets 30a and 30b. At this time, the leakage magnetic fields of the magnets 29a and 29b reach the vicinity of the targets 30a and 30b and are concentrated thereon, respectively, so that magnetron plasma is generated around the targets 30a and 30b. In this state, positive ions in the plasma collide with the targets 30a and 30b, and the sputter particles generated in the constituent material of the targets 30a and 30b are emitted from the targets 30a and 30b and deposited on the substrate W by the magnetron sputtering.

The arrangement positions and the orientations of the targets 30a and 30b by the target holders 26a and 26b may vary, and are set depending on the pattern formed on the substrate W.

The two substrate supporting units 14 are disposed in the chamber body 10a of the processing chamber 10 and are configured to support the substrates W via support pins 31. The two substrate supporting units 14 are arranged along the X direction that is one horizontal direction along the longitudinal direction of the processing chamber 10, and are configured to independently move linearly in the X direction by the substrate moving mechanism 16. Therefore, the substrates W supported by the substrate supporting units 14 are linearly moved on the horizontal plane by the substrate moving mechanism 16. The substrate moving mechanism 16 includes two robot arms (multi joint arms) 32 disposed to correspond to the two substrate supporting units 14, and a driving unit 33 for commonly driving the multi joint arms 32. The driving unit 33 drives the two robot arms (multi joint arms) 32 to move the two substrate supporting units 14 independently on a common moving path along the X direction.

The substrates W are delivered between the two substrate supporting units 14 and the vacuum transfer device 160 of the vacuum transfer chamber 120 through the two substrate loading/unloading ports 23 in a state where the gate valves G are opened. As described above, the substrate loading/unloading ports 23 are disposed in parallel in the X direction along the longitudinal side of the processing chamber 10, and the transfer direction of the substrates W at this time is the Y direction perpendicular to the X direction while the substrate supporting units 14 and the substrates W move in the X direction.

The sputter particle shielding member 18 is used for shielding sputter particles emitted from the targets 30a and 30b. The sputter particle shielding member 18 has a first member 18a horizontally disposed above the substrate supporting units 14, a second member 18b having a truncated cone shape corresponding to the shape of the lid 10b of the processing chamber 10, and a third member 18c for partitioning the inner space of the second member 18b.

A slit-shaped through-hole 19 through which sputter particles pass is formed at a central portion of the first member 18a. The through-hole 19 is narrow and elongated along the Y direction, which is one horizontal direction in the drawing, as the longitudinal direction. The length of the through-hole 19 in the Y direction is longer than the diameter of the substrate W. In this example, sputter particles are emitted from the targets 30a and 30b respectively held by the target holders 26a and 26b disposed at opposite positions, and the sputter particles that have passed through the through-hole 19 among the emitted sputter particles are obliquely incident on the substrate W and deposited thereon.

In the second member 18b, holes are formed only at the portions corresponding to the targets 30a and 30b. The first member 18a and the second member 18b are connected without a gap to prevent leakage of the sputter particles.

The third member 18c extends vertically from the center of the upper surface of the second member 18b to a position near the through-hole 19 to divide the inner space of the second member 18b into two parts, i.e., a part on the target 30a side and a part on the target 30b side. The third member 18c is used for suppressing cross contamination between the target 30a and the target 30b.

The position of the through-hole 19 is not limited to the central portion, and the through-hole 19 may be formed at an appropriate position depending on the incidence angle on the substrate W or the like, as will be described later. Although the target holders 26a and 26b (the targets 30a and 30b) are disposed at opposite positions with the through-hole 19 interposed therebetween, the present disclosure is not limited thereto, and the target holders 26a and 26b may be disposed at any other positions. In FIG. 2, the sputter particles emitted from the targets 30a and 30b pass through the through-hole 19. However, the sputter particles may pass through any other through-holes.

The controller 40 functions as a lower-level controller of the overall controller 150, and is configured as a computer. The controller 40 controls the individual components of the film forming apparatus 110, e.g., the sputter particle emitting units 12a and 12b, the substrate moving mechanism 16, the exhaust device 20, and the like. The controller 40 has a main controller including a CPU that actually controls the above components, an input device, an output device, a display device, and a storage device. The storage device stores parameters of various processes executed by the film forming apparatus 110, and a storage medium for storing programs, i.e., processing recipes, for controlling the processes executed by the film forming apparatus 110, is set in the storage device. The main controller of the controller 40 retrieves a predetermined processing recipe stored in the storage medium, and causes the film forming apparatus 110 to execute predetermined processing based on the retrieved processing recipe.

<Example of Film Forming Method>

Next, an example of a film forming method in the film forming apparatus configured as described above will be described. The following processes are performed under the control of the controller 40.

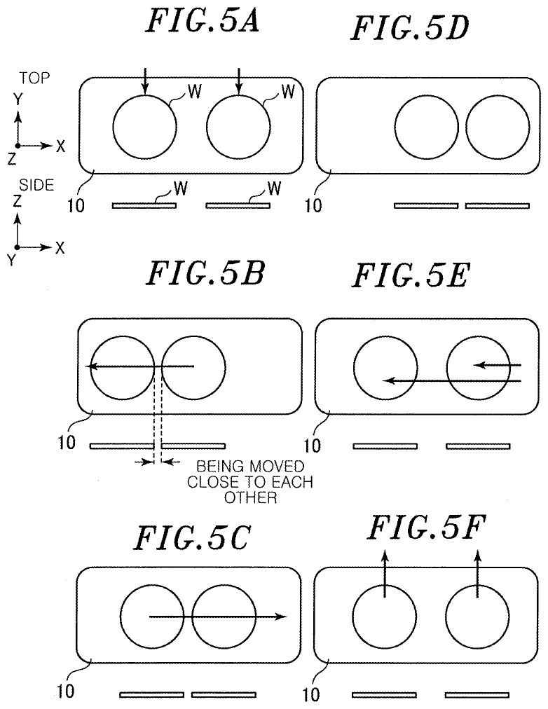

First, the outline of the movement of the substrates W in the film forming method of this example will be described with reference to FIGS. 5A to 5F. FIGS. 5A to 5F schematically show the states viewed from the top and the side. First, two substrates W are loaded into the chamber 10 from the loading/unloading ports 23 and placed on the substrate supporting units 14 (see FIG. 5A). Next, the two substrates W are moved close to each other and also moved to a film formation start position on one side of the chamber 10 in the X direction (see FIG. 5B). Then, sputter film formation is performed while moving (scanning) the two substrates W simultaneously along the X direction (see FIG. 5C). When the substrates W reach a film formation end position, the movement of the substrates W is stopped to end the film formation (see FIG. 5D). Thereafter, the substrates W are moved to the positions corresponding to the loading/unloading ports 23 (see FIG. 5E), and unloaded from the loading/unloading ports 23 (see FIG. 5F).

Next, the film forming method of this example will be described in detail.

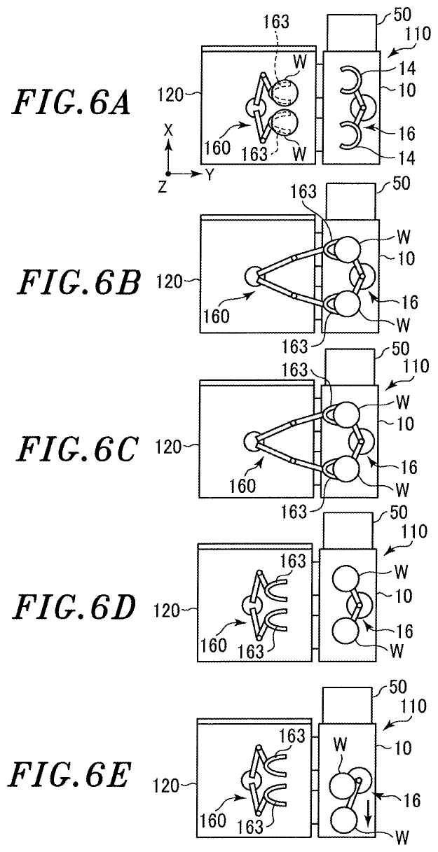

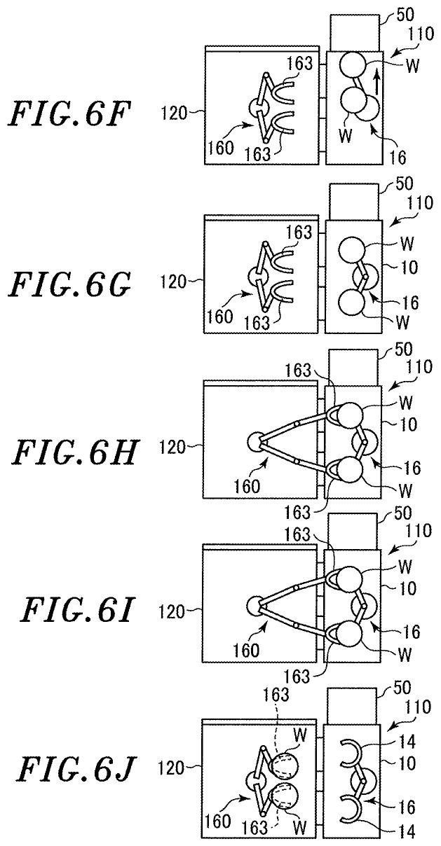

FIGS. 6A to 6J explain transfer states of the substrates in the case of performing the film forming method of this example.

In the case of performing the film forming method, prior to the film formation, the processing space S in the processing chamber 10 is exhausted, and a sputtering gas, e.g., an inert gas, is introduced into the processing space S from the gas inlet port 22 to adjust a pressure therein to a predetermined pressure.

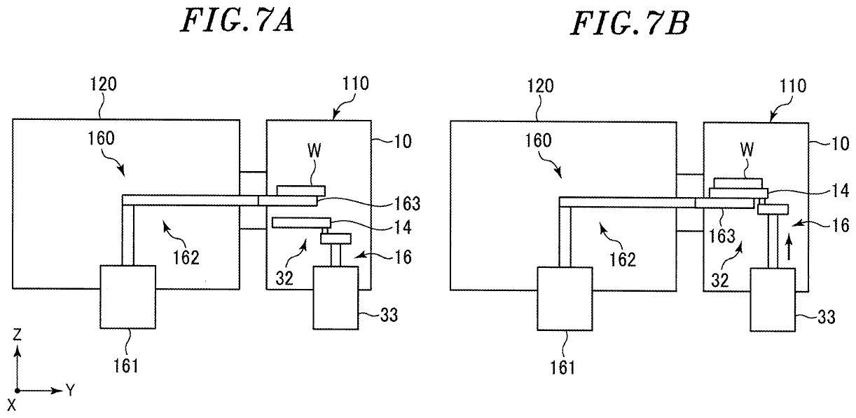

In that state, first, the substrate supporting units 14 are located at substrate delivery positions (see FIG. 6A). Next, the gate valves G are opened, and the two substrates W supported by the two substrate holders 163 of the vacuum transfer device 160 in the vacuum transfer chamber 120 are loaded into the processing chamber 10 and placed on the positions corresponding to the substrate supporting units 14 (see FIG. 6B). At this time, as shown in FIG. 7A, the substrate holders 163 supporting the substrates W are positioned above the substrate supporting units 14.

Next, the substrates W of the substrate holders 163 are delivered to the substrate supporting units 14 (see FIG. 6C). At this time, as shown in FIG. 7B, the robot arms (the multi-joint arms) 32 are raised so that the substrates W on the substrate holders 163 are received by the substrate supporting units 14.

Next, the substrate holders 163 of the vacuum transfer device 160 are returned to the vacuum transfer chamber 120 (see FIG. 6D). At the same time, the gate valves G are closed.

Next, the substrate moving mechanism 16 moves the two substrate supporting units 14 on which the substrates W are placed close to each other, and the substrate supporting units 14 placed close to each other are moved together with the substrates W to the film formation start position on one side in the X direction (see FIG. 6E).

Next, the sputter film formation is performed on the substrates W while simultaneously moving (scanning) the two substrates W placed on the substrate supporting units 14 along the same moving path in the same direction along the X direction using the substrate moving mechanism 16 (see FIG. 6F). In the sputter film formation at this time, the sputter particles are emitted from one or both of the targets 30a and 30b and deposited on the substrates W while the two substrates W are moving along the X direction. As shown in FIG. 6F, when the substrates W reach the film formation end position, the movement of the substrates W is stopped to end the film formation.

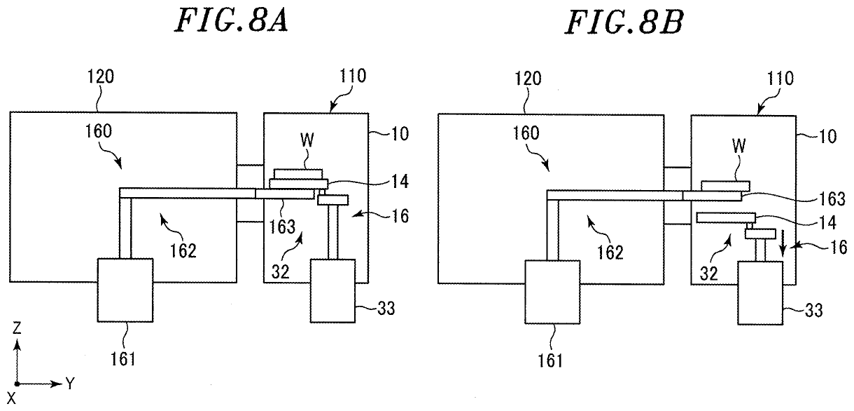

Upon completion of the film formation, the two substrate supporting units on which the substrates W are placed are moved to positions corresponding to the substrate loading/unloading ports 23 (see FIG. 6G). Then, the gate valves G are opened, and the two substrate holders 163 of the vacuum transfer device 160 are located at positions corresponding to the two substrate supporting units 14 on which the substrates W are placed (see FIG. 6H). At this time, as shown in FIG. 8A, the substrate holders 163 are located below the substrate supporting units 14 on which the substrates W are placed.

Next, when the substrates W on the substrate supporting units 14 are delivered to the substrate holders 163 (see FIG. 6I), the robot arms (the multi joint arms) 32 are lowered so that the substrates W on the substrate supporting units 14 are received by the substrate holders 163 as shown in FIG. 8B.

Next, the substrate holders 163 that have received the substrates W are returned to the vacuum transfer chamber 120 (see FIG. 6J). At the same time, the gate valves G are closed.

Next, the film formation will be described in detail.

As described above, in the present embodiment, in a state where the two substrates W are simultaneously moved along the common moving path extending in the X direction, the sputter particles are emitted from one or both of the targets 30a and 30b and deposited on the substrates W.

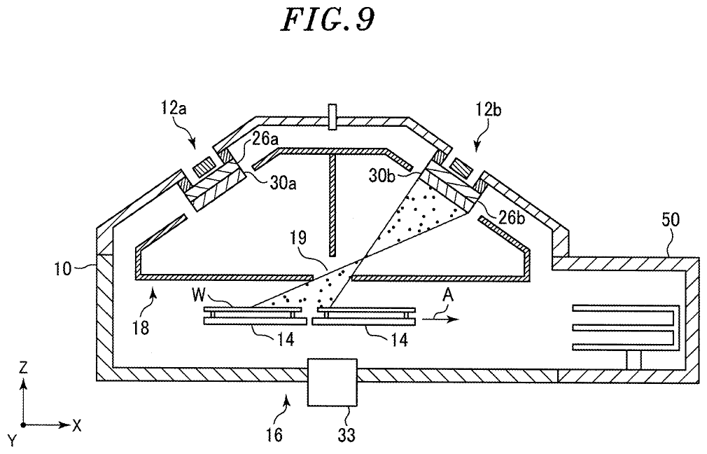

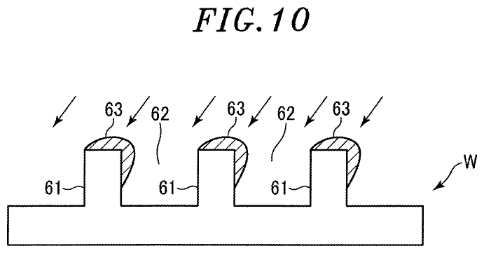

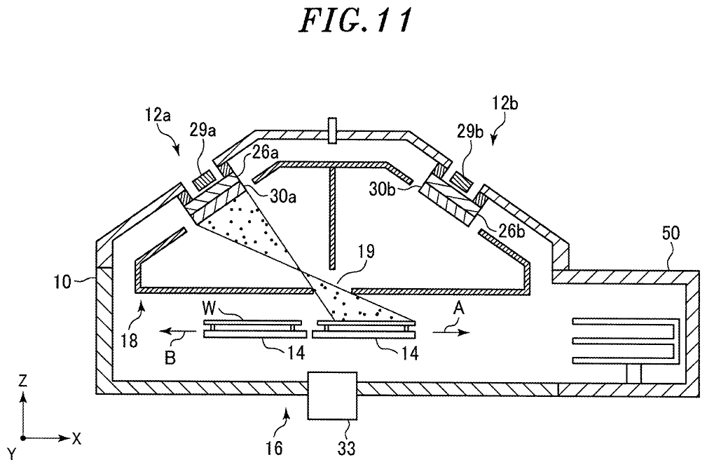

For example, as shown in FIG. 9, the sputter particles are emitted obliquely downward from the target 30b of the sputter particle emitting unit 12b in a state where the substrates W are moved in a direction of an arrow A along the X direction. At this time, the sputter particles pass through the slit-shaped through-hole 19, and then are obliquely incident on the two substrates Won the two substrate supporting units 14 and deposited thereon. For example, as shown in FIG. 10, films 63 are obliquely formed on convex portions 61 of the substrate W having a trench pattern in which the convex portions 61 and trenches 62 that are concave portions are alternately formed.

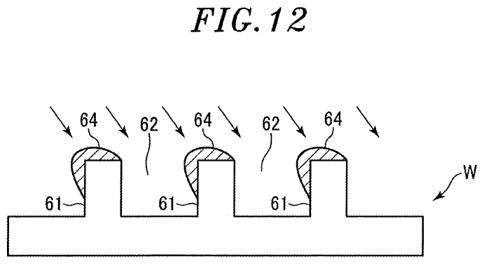

As shown in FIG. 11, the sputter particles may be emitted from the target 30a. In this case as well, the sputter particles pass through the through-hole 19, and then are obliquely incident on the two substrates W on the two substrate supporting units 14 from the opposite side to that in FIG. 9 and deposited thereon. For example, as shown in FIG. 12, films 64 are obliquely formed from the opposite side to that in FIG. 10 on the convex portions 61 of the substrate W having a trench pattern in which the convex portions 61 and the trenches 62 that are the concave portions are alternately formed.

In any of the above cases, the movement direction of the substrate W is not limited to the direction of the arrow A, and may be a direction of an arrow B that is opposite to the direction of the A direction shown in FIG. 11.

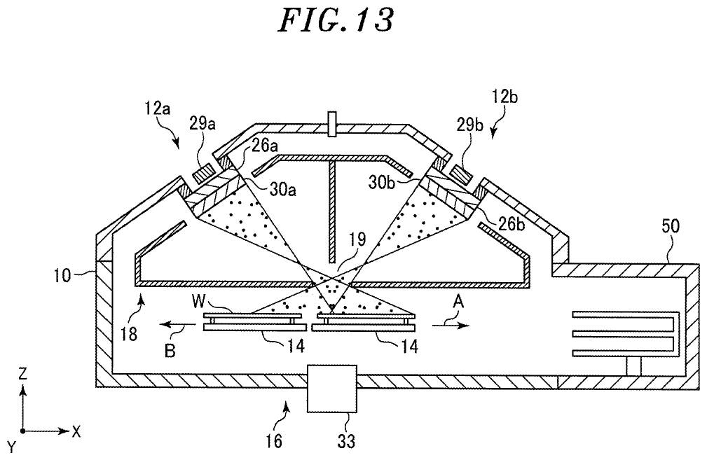

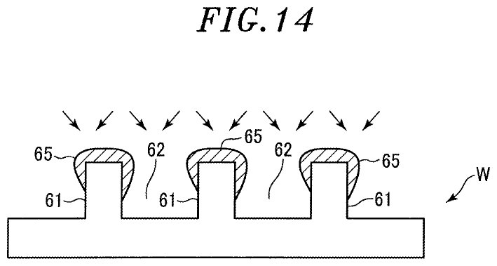

As shown in FIG. 13, the sputter particles may be emitted from both the targets 30a and 30b. In this case as well, the sputter particles pass through the through-hole 19, and then are obliquely incident on the two substrates W on the two substrate supporting units 14 and deposited thereon. The movement direction of the substrate W may be the direction of the arrow A or may be the direction of the arrow B. In this case, as shown in FIG. 14, for example, the sputter particles are irradiated from both directions to the substrate W having a trench pattern in which the convex portions 61 and the trenches 62 that are the concave portions are alternately formed, so that films 65 that overhang on both sides can be formed at the upper portions of the convex portions 61.

The above-described film formation may be performed once or may be repeated multiple times. In the case of repetitively performing the film formation with a single target multiple times, a same target may be used or different targets may be used alternately. Further, in the case of repeating the film formation multiple times, the movement direction of the substrate W may be either the direction of the arrow A or the direction of the arrow B. Alternatively, the direction of the arrow A and the direction of the arrow B may be alternately used as the movement direction of the substrate W.

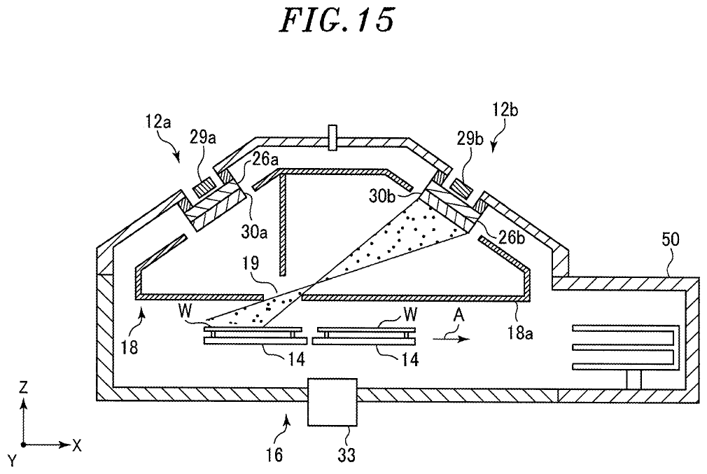

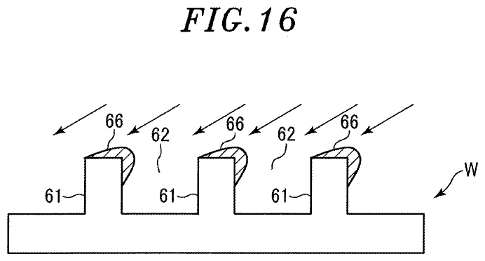

The position of the through-hole 19 of the sputter particle shielding member 18 can be arbitrarily set, and the incidence angle of the sputter particles on the substrate W can be freely set depending on the position of the through-hole 19, which makes it possible to adjust the directivity. For example, as shown in FIG. 15, by setting the position of the through-hole 19 on the end side, the incidence angle of the sputter particles incident on the substrate W can be reduced, and the directivity of the sputter particles can be improved. Specifically, as shown in FIG. 16, the sputter particles can be incident at a smaller angle than that in FIG. 10 on the substrate W having a trench pattern in which the convex portions 61 and the trenches 62 that are the concave portions are alternately formed, so that films 66 having improved directivity can be formed at the upper portions of the convex portions 61. Further, the moving distance of the substrate W can be adjusted by the position of the through-hole.

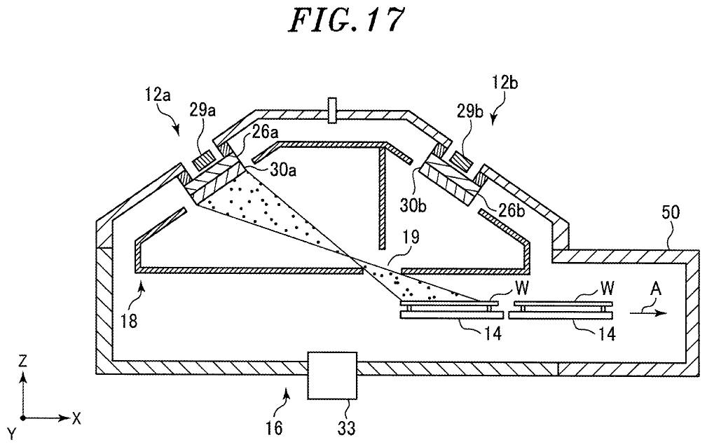

If the position of the through-hole 19 is set on the end side, the moving distance of the substrate W may not be within the length of the processing chamber 10. In that case, as shown in FIG. 17, the preliminary chamber 50 can be used as a part of the processing chamber 10.

Further, as shown in FIG. 4, by allowing the preliminary chamber 50 to have the function of rotating the substrate W, the incidence direction of the sputter particles on the substrate W can be freely adjusted.

In accordance with the present embodiment, after the two substrates W are loaded into the processing chamber 10 and placed on the substrate supporting units 14, the two substrates W are subjected to the film formation while moving along the common moving path extending in the X direction. Accordingly, the two substrates W can be processed simultaneously, and the film formation can be performed with a higher throughput compared to that in the film forming apparatus for performing sputter film formation while moving one substrate as described in Japanese Patent Application Publication 2020-26575. Since the film formation is performed while simultaneously moving the two substrates W along the common moving path, the space per one substrate can be reduced and the space can be saved. Further, since the two substrates W are loaded and unloaded from the two loading/unloading ports 23 disposed in parallel along the Y direction perpendicular to the X direction that is the movement direction of the substrates W, the two substrates W can be simultaneously loaded and unloaded and the space-saving effect can be further improved. Moreover, since the two substrates W are loaded into the processing chamber 10 and moved close to each other in the movement direction, the total moving distance of the two substrates W can be shortened by that amount, which makes it possible to further save the space.

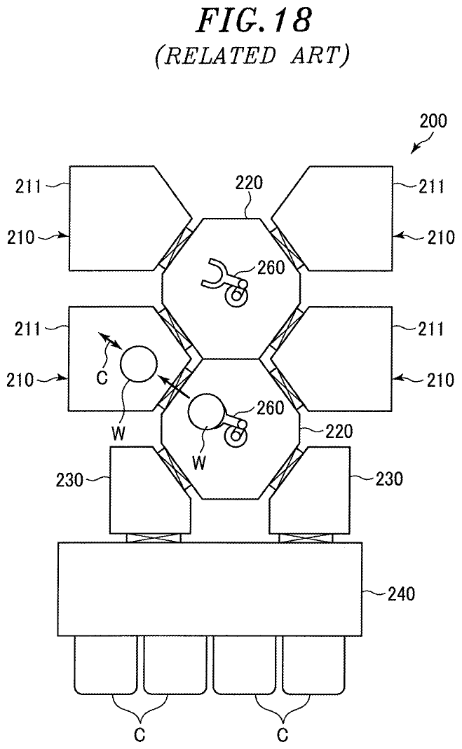

The film forming apparatus disclosed in Japanese Patent Application Publication 2020-26575 has the configuration of a film forming apparatus 210 connected to a vacuum transfer chamber 220 in a film forming system 200 shown in FIG. 18, for example. The loading/unloading direction of the substrate W into/from the processing chamber 211 is the same as a direction of an arrow C that is the movement direction of the substrate W in the processing chamber 211. A reference numeral 230 indicates a load-lock chamber. A reference numeral 240 indicates an atmospheric transfer chamber. A reference numeral 260 indicates a vacuum transfer device.

If a dual-wafer film forming apparatus is designed in the same manner as that disclosed in Japanese Patent Application Publication 2020-26575, it will be required to perform film formation on two substrates loaded from the loading/unloading ports while moving the two substrates along separate transfer paths parallel to the direction of the arrow C, which increases the footprint of the apparatus. Further, it is necessary to provide a sputter particle emitting unit (target) for each substrate, so that the equipment is scaled up.

On the other hand, in the present embodiment, as described above, the film formation is performed on the two substrates W loaded from the two loading/unloading ports 23 while simultaneously moving the two substrates along the common moving path extending in the X direction. Therefore, the space can be saved compared to the case of Japanese Patent Application Publication 2020-26575. Further, since the two substrates W are loaded and unloaded from the two loading/unloading ports 23 disposed in parallel along the Y direction perpendicular to the X direction that is the movement direction of the substrates W, the space-saving effect can be further improved. Since the space of the film forming apparatus 100 can be saved, the entire space of the film forming system 100 can be saved.

Further, in accordance with the present embodiment, the sputter particles that have passed through the slit-shaped through-holes 19 from the diagonally arranged targets 30a and 30b are obliquely incident on the substrates W and deposited thereon, so that the films having improved directivity can be formed on the substrates W.

Further, in the film forming apparatus 110 of the present embodiment, the two sputter particle emitting units 12a and 12b are provided, and the sputter particles are emitted from one or both of the targets 30a and 30b attached to the two sputter particle emitting units 12a and 12b and deposited on the substrate W. Therefore, the sputter film formation with an extremely high degree of freedom can be realized by different combinations of the targets to be used and the movement directions of the substrates W.

Further, by adjusting the position of the through-hole 19 through which the sputter particles pass, the incidence angle of the sputter particles on the substrate W and the moving distance of the substrate W can be freely set. Moreover, by using the preliminary chamber 50 as a part of the processing chamber 10, it is possible to cope with a case in which the moving distance of the substrate W gets longer due to the adjustment of the position of the through-hole 19. Furthermore, by allowing the preliminary chamber 50 to have the function of rotating the substrate W, the incidence direction of the sputter particles on the substrate W can be freely adjusted.

<Another Example of Film Forming Apparatus>

Next, another example of the film forming apparatus will be described.

In the above-described example of the film forming apparatus, the substrate moving mechanism 16 including the robot arms (the multi joint arms) 32 and the driving unit 33 and configured to move the substrate supporting units 14 is illustrated as the substrate moving mechanism for moving the substrate supporting units 14 on which the substrates W are placed. However, the substrate moving mechanism is not limited thereto as long as the substrate supporting units 14 can be moved in the X direction.

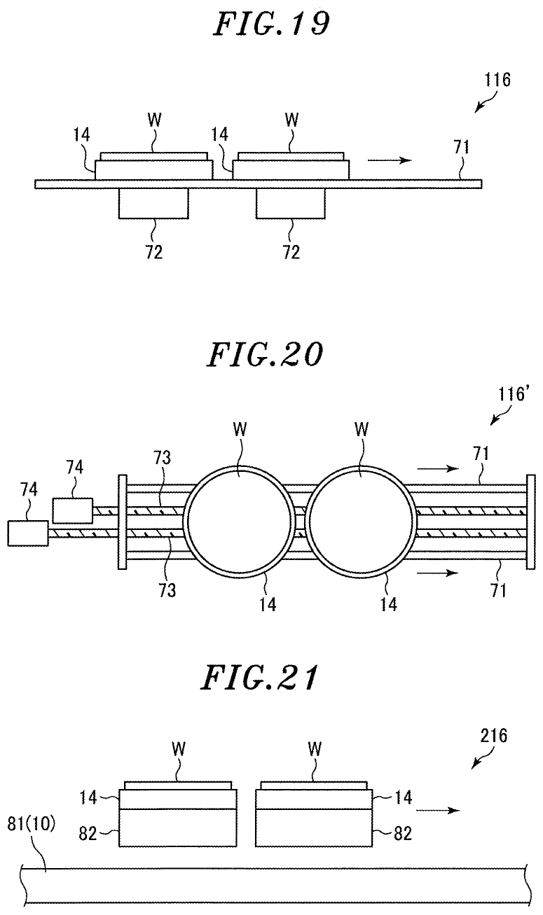

For example, as shown in FIG. 19, a substrate moving mechanism 116 including a rail 71 for guiding the two substrate supporting units 14 in the X direction and two driving mechanisms 72 for independently moving the substrate supporting units 14 in the X direction may be used. As shown in FIG. 20, a substrate moving mechanism 116′ using a ball screw mechanism as a driving mechanism may be used. In other words, the substrate supporting units 14 are moved along the rail 71 by the rotation of two ball screws 73 using a driving mechanism including the two ball screws 73 screwed into the respective substrate supporting units 14 and two driving motors 74 for rotating the respective ball screws 73.

Further, as shown in FIG. 21, a substrate moving mechanism 216 using a planar motor may be used. In other words, the substrate moving mechanism 216 includes a planar motor 81 formed by embedding a plurality of electromagnetic coils in the bottom of the processing chamber 10, and two bases 82 disposed to support the respective substrate supporting units 14 and having therein a plurality of permanent magnets. In this substrate moving mechanism 216, a current is supplied to the electromagnetic coils of the planar motor 81 in a direction that the magnetic field generated by the current repels the permanent magnets to magnetically deviate the bases 82 accordingly. Then, the substrate supporting units 14 are moved in the X direction by individually controlling the current supplied to the electromagnetic coils.

<Another Example of Film Forming Method>

Next, another example of the film forming method will be described.

In the above-described example of the film forming method, two substrates W are moved close to each other at the time of performing film formation to save the space. However, in this example, two substrates W are stacked in a height direction at the time of start and end of the film formation to save the space in a different manner. The vertical movement of the substrates W during the film formation can be realized by vertically moving the multi-joint arms 32 of the substrate moving mechanism 16, for example.

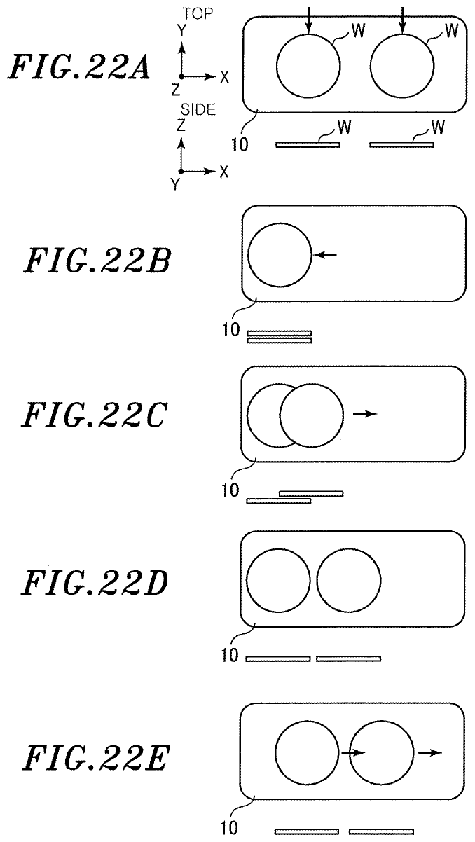

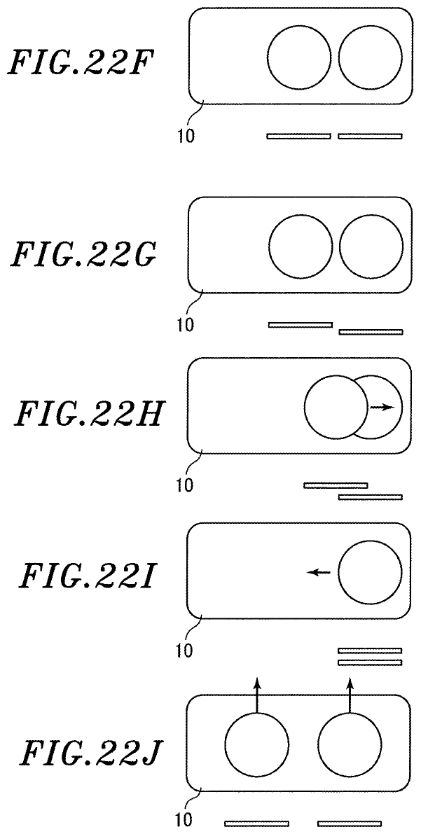

FIGS. 22A to 22J explain the movement of the substrates in the case of performing another example of the film forming method, and schematically show the states viewed from the top and the side.

First, the two substrates W are loaded (see FIG. 22A). The positions of the substrates W at this time are the same as those in FIG. 5A. Next, the two substrates W are moved to one end of the processing chamber 10 to overlap each other in the height direction (see FIG. 22B). In that state, the upper substrate W is moved toward the other end of the processing chamber 10 along the X direction and subjected to the film formation (see FIG. 22C). Then, when the overlapping of the two substrates W is released, the height positions of the two substrates W are aligned (see FIG. 22D). Thereafter, the two substrates W are simultaneously moved toward the other end of the processing chamber 10 along the X direction and subjected to the film formation (see FIG. 22E). When the substrate W in the front reaches the other end, the movement of this substrate W in the X direction is stopped and the film formation is ended (see FIG. 22F). While the film formation on the substrate W behind continues, the height positions of the two substrates W are adjusted such that the position of the substrate behind W becomes higher than that of the substrate W in the front (see FIG. 22G). Then, the substrate W behind is moved toward the other end of the processing chamber 10 (see FIG. 22H). When the two substrates W overlap each other in the height direction at the other end of the processing chamber 10, the movement of the substrate W behind is stopped and the film formation is ended (see FIG. 22I). Next, the two substrates W are moved to the positions corresponding to the loading/unloading ports (not shown) and unloaded from the processing chamber 10 (see FIG. 22J).

By stacking the two substrates in the height direction at the time of start and end of the film formation, the processing chamber 10 can be further scaled down, and another space saving can be realized.

<Other Applications>

While the embodiments have been described above, the embodiments of the present disclosure are illustrative in all respects and are not restrictive. The above-described embodiments can be embodied in various forms. Further, the above-described embodiments may be omitted, replaced, or changed in various forms without departing from the scope of the appended claims and the gist thereof.

For example, in the above-described embodiment, the case in which the film formation is performed on two substrates has been described. However, the number of substrates is not limited thereto, and the number of substrates may be three or more as long as there are multiple substrates.

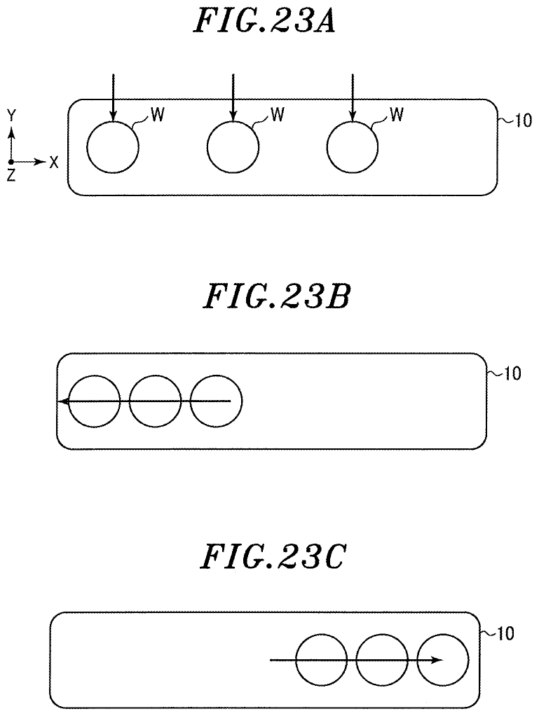

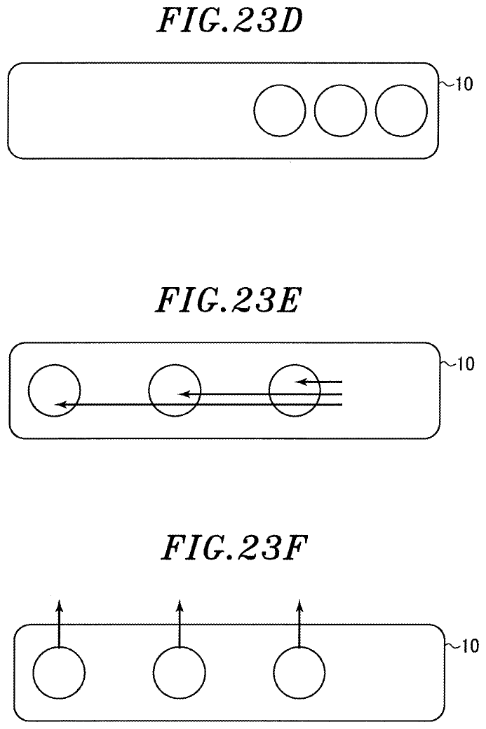

For example, the outline of the movement of three substrates W in the case of performing the film formation on the three substrates W will be described with reference to FIGS. 23A to 23F. Similarly to the case where the number of substrates W is two as shown in FIGS. 5A to 5F, in the case where the number of substrates W is three, first, the three substrates W are loaded into the chamber 10 from three loading/unloading ports and placed on the substrate supporting units (see FIG. 23A). Next, the three substrates W are moved close to one another and moved to the film formation start position on one side of the chamber 10 in the X direction (see FIG. 23B). Next, the sputter film formation is performed while simultaneously moving (scanning) the three substrates W along the X direction (see FIG. 23C). When the substrates W reach the film formation end position, the movement of the substrates W is stopped to end the film formation (see FIG. 23D). Then, the substrates W are moved to the position corresponding to the loading/unloading ports (see FIG. 23E) and unloaded (see FIG. 23F). This is also applied to the case where there are four or more substrates W.

In the above-described embodiment, the example in which the substrates W are arranged in the movement direction of the substrates W has been described. However, the present disclosure is not limited thereto, and the substrates W may be arranged in a direction perpendicular to the movement direction of the substrates W.

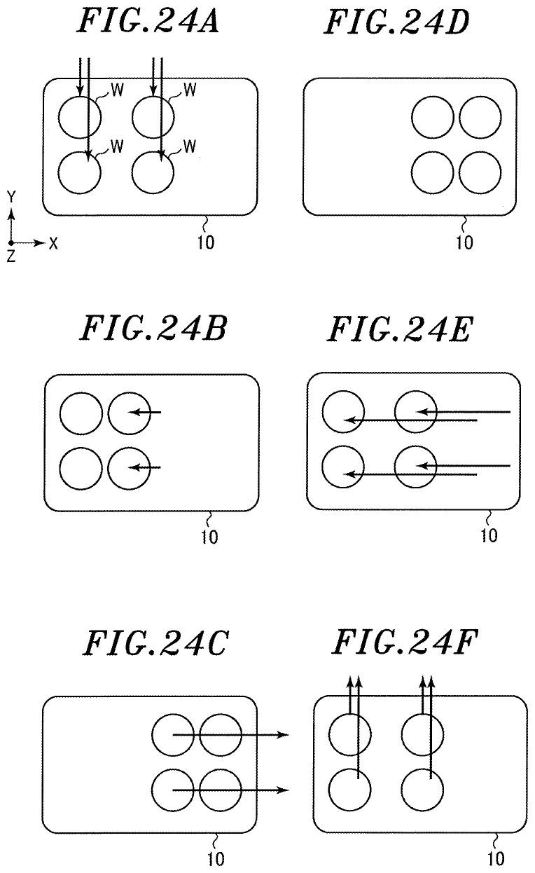

For example, the outline of the movement of four substrates W in the case of performing film formation on the four substrates W arranged in a 2×2 matrix having two rows in the X direction that is the movement direction of the substrates W and two columns in the Y direction perpendicular to the X direction will be described with reference to FIGS. 24A to 24F. First, the four substrates W, i.e., two substrates W from each of two loading/unloading ports, are loaded into the chamber 10 and placed on four substrate supporting units arranged in two rows in the X direction and in two columns in the Y direction (see FIG. 24A). Next, the two substrates W arranged in the X direction are moved close to each other and moved to the film formation start position on one side of the chamber 10 in the X direction (see FIG. 24B). Next, the sputter film formation is performed while simultaneously moving (scanning) the four substrates W along the X direction (see FIG. 24C). When the substrates W reach the film formation end position, the movement of the substrates W is stopped to end the film formation (see FIG. 24D). Then, the substrates W are moved to the positions corresponding to the loading/unloading ports (see FIG. 24E), and unloaded (see FIG. 24F).

When three or more substrates W are arranged in the X direction that is the movement direction of the substrates W, the substrates W may be stacked in the height direction at the film formation start position and sequentially moved as in the case of FIGS. 22A to 22J.

The technique of emitting the sputter particles in the above-described embodiment is an example, and the sputter particles may be emitted by another technique.

In the above-described embodiment, the example in which two targets (the sputter particle emitting units) are provided has been described. However, the number of the targets may be one, or three or more.

Further, in the above-described embodiment, the case where the sputter particles are emitted from one target or both targets while moving the substrates in one direction has been described. However, the sputter particles may be emitted from two targets alternately while moving the substrates in one direction.

Although the above-described embodiment has described the example in which three film forming apparatuses are connected around the vacuum transfer chamber, the number of the film forming apparatuses is not limited thereto. Further, a plurality of vacuum transfer chambers may be connected, and the film forming apparatuses may be connected to respective vacuum transfer chambers.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming apparatus comprising:
a processing chamber accommodating a plurality of substrates;
a plurality of substrate supporting units disposed in the processing chamber and configured to place the substrates thereon;
a substrate moving mechanism configured to linearly move the substrate supporting units in a first direction;
sputter particle emitting units, each having a target for emitting sputter particles into the processing chamber; and
a controller configured to control the sputter particle emitting units and the substrate moving mechanism,
wherein the controller controls the substrate moving mechanism to linearly move the substrate supporting units on which the substrates are placed in the first direction and controls the sputter particle emitting units to emit sputter particles to be deposited on the substrates.

2. The film forming apparatus of claim 1, wherein the processing chamber accommodates two substrates and the number of the substrate supporting units is two.

3. The film forming apparatus of claim 1, wherein the substrate supporting units are arranged along the first direction.

4. The film forming apparatus of claim 3, wherein the processing chamber has a plurality of substrate loading/unloading ports disposed in parallel along the first direction and configured to load and unload the substrates, and the substrates are loaded into and unloaded from the chamber through the substrate loading/unloading ports along a second direction perpendicular to the first direction.

5. The film forming apparatus of claim 4, wherein the controller controls, after the substrates are loaded into the processing chamber, the substrate moving mechanism to move the substrates to a film formation start position on one side of the processing chamber and to a film formation end position on the other side of the processing chamber.

6. The film forming apparatus of claim 5, wherein the controller controls the substrate moving mechanism such that the substrates moved to the film formation start position are located close to each other.

7. The film forming apparatus of claim 5, wherein the controller controls the substrate moving mechanism such that the substrates moved to the film formation start position overlap each other in a height direction.

8. The film forming apparatus of claim 1, further comprising:
a sputter particle shielding member having a through-hole through which the sputter particles emitted from the sputter particle emitting units pass and are guided toward the substrates placed on the substrate supporting units,
wherein the sputter particles are obliquely incident on the substrates.

9. The film forming apparatus of claim 8, wherein directivity of the sputter particles is adjusted by adjusting a position of the through-hole.

10. The film forming apparatus of claim 1, wherein the number of the sputter particle emitting units is two, and the controller controls one or both of the two sputter particle emitting units to emit sputter particles.

11. The film forming apparatus of claim 1, wherein the substrate moving mechanism includes a plurality of robot arms respectively corresponding to the plurality of substrate supporting units, a rail for guiding the substrate supporting units, or a planar motor configured to magnetically levitate and move the substrate supporting units.

12. The film forming apparatus of claim 1, further comprising:
a preliminary chamber connected to an end portion of the processing chamber in the first direction and communicating with the processing chamber,
wherein the preliminary chamber has a function of holding a substrate as a buffer unit, a function of rotating the substrate therein, or a function as a part of the processing chamber.

13. A film forming system comprising:
a film forming apparatus configured to simultaneously perform sputter film formation on a plurality of substrates;
a transfer chamber; and
a transfer device configured to transfer the substrates with respect to the film forming apparatus disposed in the transfer chamber,
wherein the film forming apparatus includes:
a processing chamber connected to the transfer chamber through a plurality of substrate loading/unloading ports and accommodating the substrates;
a plurality of substrate supporting units disposed in the processing chamber and configured to place thereon the substrates transferred by the transfer device;
a substrate moving mechanism configured to linearly move the substrate supporting units in a first direction;
a sputter particle emitting unit having a target for emitting sputter particles into the processing chamber; and a controller configured to control the sputter particle emitting unit and the substrate moving mechanism,
wherein the controller controls the substrate moving mechanism to linearly move the substrate supporting units on which the substrates are placed in the first direction and controls the sputter particle emitting unit to emit sputter particles to be deposited on the substrates.

14. The film forming system of claim 13, wherein the processing chamber accommodates two substrates and the number of the substrate supporting units is two.

15. The film forming system of claim 13, wherein the substrate supporting units are arranged along the first direction.

16. The film forming system of claim 15, wherein the transfer device loads the substrates into the chamber from the substrate loading/unloading ports along a second direction perpendicular to the first direction.

17. A film forming method for forming a film using a film forming apparatus,
wherein the film forming apparatus includes a processing chamber accommodating a plurality of substrates, a plurality of substrate supporting units disposed in the processing chamber and configured to place the substrates thereon, a substrate moving mechanism configured to linearly move the substrate supporting units in a first direction, and sputter particle emitting units, each having a target for emitting sputter particles into the processing chamber,
the film forming method comprising:
loading the substrates into the processing chamber and placing the substrates on the respective substrate supporting units;
linearly moving the substrate supporting units on which the substrates are placed in the first direction; and
emitting the sputter particles from the sputter particle emitting units while moving the substrate supporting units, so as for the sputter particles to be deposited on the substrates.

18. The film forming method of claim 17, wherein the processing chamber accommodates two substrates and the number of the substrate supporting units is two.

19. The film forming method of claim 17, wherein the substrate supporting units are arranged along the first direction.

20. The film forming method of claim 19, wherein the processing chamber has a plurality of substrate loading/unloading ports arranged in parallel along the first direction and configured to load and unload the substrates, and
the substrates are loaded into the chamber from the substrate loading/unloading ports along a second direction perpendicular to the first direction.

21. The film forming method of claim 20, wherein after the substrates are loaded into the processing chamber, the substrates are moved to a film formation start position on one side of the processing chamber and then moved to a film formation end position on the other side of the processing chamber.

22. The film forming method of claim 21, wherein the substrate moving mechanism is controlled such that the substrates moved to the film formation start position are located close to each other.

23. The film forming method of claim 21, wherein the substrate moving mechanism is controlled such that the substrates moved to the film formation start position overlap each other in a height direction.

24. The film forming method of claim 17, wherein in said emitting the sputter particles from the sputter particle emitting units so as for the sputter particles to be deposited on the substrates, the sputter particles emitted from the sputter particle emitting units pass through a through-hole of a sputter particle shielding member and are obliquely incident on the substrates.

25. The film forming method of claim 17, wherein the number of the sputter particle emitting units of the film forming apparatus is two, and
in said emitting the sputter particles from the sputter particle emitting units so as for the sputter particles to be deposited on the substrates, the sputter particles are emitted from one or both of the two sputter particle emitting units.
